(19) United States
(12) Patent Application Publication
(10) Pub. No.: US 2018/0016675 A1
(43) Pub. Date: Jan. 18, 2018

(54) VACUUM CHAMBER HAVING A SPECIAL DESIGN FOR INCREASING THE REMOVAL OF HEAT

(71) Applicant: OERLIKON SURFACE SOLUTIONS AG, PFAEFFIKON, Pfaeffikon (CH)

(72) Inventors: Siegfried KRASSNITZER, Feldkirch (AT); Markus ESSELBACH, Feldkirch (AT)

(73) Assignee: OERLIKON SURFACE SOLUTIONS AG, PFAEFFIKON, Pfaeffikon (CH)

(21) Appl. No.: 15/544,430

(22) PCT Filed: Jan. 15, 2016
(86) PCT No.: PCT/EP2016/050841

§ 371 Date: Jul. 18, 2017

Related U.S. Application Data
(60) Provisional application No. 62/104,918, filed on Jan. 19, 2015.
(60) Provisional application No. 62/117,571, filed on Feb. 18, 2015.

(51) Int. Cl. C23C 14/54; C23C 14/24

(52) U.S. Cl. CPC C23C 14/541; C23C 14/24

(57) ABSTRACT

The invention relates to a vacuum chamber for the treatment of substances, comprising at least the following elements:
heat supply elements for the heat supply into a treatment area of the vacuum chamber, in which at least one substrate (10) can be treated,
a chamber wall (20), through which heat can be removed from the treatment area, comprising an inner and an outer chamber wall side, and
a shielding wall (30), which is arranged between the chamber wall (20) and the treatment area, such that an averted shielding wall side regarding to the treatment area is placed opposite the inner chamber wall side,
   and characterized in, that
the shielding wall side placed opposite the inner chamber wall side is at least partially, preferred largely applied with a first coating (31), which has an emission coefficient ε≧0.65.

The present invention relates to a vacuum chamber and a coating system having a special design for increasing the removal of heat.

### STATE OF THE ART

Conventional coating systems are usually designed in such a way, that a predeterminable coating temperature inside the coating chamber or of the recipient, respectively, can be realized and maintained. The surfaces inside the coating chamber are often made of shiny or blasted stainless steel or aluminum. Since the inner walls of the coating chamber can be undesirably coated during performing coating processes, a shielding is usually used, in order to avoid the build-up of thicker coatings on the inner walls. Above all, the use of such a shielding is very helpful when several coating processes should be performed one after the other without service and, as a result, several coatings accumulate on one another and flaking occurs during coating and after coating. Such a shielding is often also made of shiny or blasted stainless steel or aluminum. This design is normally applied uniformly throughout the recipient or along the outer surface, the top surface and the bottom surface, respectively.

Coating sources, heating and cooling elements are usually distributed as individual components inside the coating chamber in such a way, that some inner surfaces or inner chamber wall surfaces, respectively will remain free of sources and/or elements. As a result these “free” surfaces act as heat removing elements or in a manner similar to cooling elements, respectively.

Usually the relation between heat supply by heating and coating sources for example, and heat removal through the outer surface of the coating chamber plays an important role when adjusting the operating point of the system regarding coating temperature, in particular when both the top surface and the bottom surface are thermally insulated. Thermally insulation of top surfaces and bottom surfaces results in a homogeneous distribution of temperature over the coating height, even if, for example, operating heaters without temperature control.

Already when starting a coating process a determined temperature, i.e. a determined temperature of the substrate surface to be coated should be realized. Heating elements are often arranged on a chamber wall surface for heat supply, at least until starting the coating process, so that these warm surfaces emit heat to the substrate.

After starting and during operating the coating process, an additional heat supply is produced by operating the coating sources, which can be particularly high when operating a great number of arc evaporation sources with high arc currents.

If substrates in a coating system were coated with a certain coating, but it was intended to establish an increased coating rate, this could be realized by using, for example, an increased number of coating sources. But in this case a corresponding increase in heat supply into the coating chamber must be expected, what resulting directly to an increase of the coating temperature, if the heat removal is not accordingly adjusted or increased. This problem is particularly severe, when using arc evaporation sources.

### OBJECT OF THE PRESENT INVENTION

An object of the invention is, to provide a solution, which makes it possible to control the heat removal in a coating chamber in such a way, that the coating temperature does not rise uncontrolled due to an increase in the heat supply, but can be held at the desired operating point.

### SOLUTION ACCORDING TO THE INVENTION

This problem is solved according to the invention, that a vacuum chamber according to claims 1 to 10 and a coating system according to claims 11 to 14 are provided.

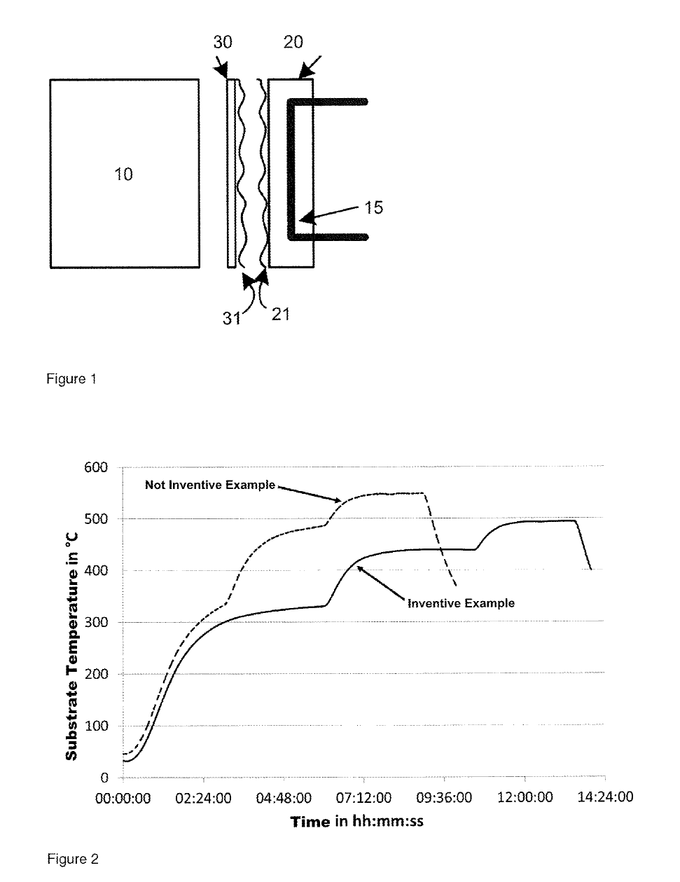

For a better understanding of the present invention it is referred to FIGS. 1 and 2:

FIG. 1 shows a schematic representation of the arrangement of basic elements of a vacuum chamber according to the present invention.

FIG. 2 shows the course of the temperature of substrates to be treated, each were treated in a vacuum chamber from the state of the art (broken line) and in a vacuum chamber according to the invention (solid line).

The present invention basically discloses a vacuum chamber for treating substrates comprising at least the following elements:
heat supply elements for the heat supply into a treatment area of the vacuum chamber in which at least one substrate 10 can be treated,
a chamber wall 20 through which heat can be removed from the treatment area comprising an inner and an outer chamber wall side, and:
a shielding wall 30 which is arranged between the chamber wall 20 and the treatment area, such that an averted shielding wall side with respect to the treatment area is placed opposite the inner chamber wall side,
   and characterized in, that
the shielding wall side placed opposite the inner chamber wall side is at least partially, preferred largely applied with a first coating 31, which has an emission coefficient ε≧0.65.

According to a preferred embodiment of the present invention the inner chamber wall side is also at least partially, preferably at least largely applied with a second coating 21 which has an emission coefficient ε≧0.65.

According to a further preferred embodiment of the present invention the chamber wall 20 comprises an integrated cooling system 15.

The emission coefficient of the first coating 31 is preferably higher than or equal to 0.80, more preferably higher than or equal to 0.90.

The emission coefficient of the second coating 21 is also preferably higher than or equal to 0.80, more preferably higher than or equal to 0.90.

Generally, the inventors have observed a particularly significant increase in heat removal from ε≧0.8, in particular from ε≧0.9. Even more preferably ε is close to 1.

According to another preferred embodiment of the present invention the first coating 31 and/or the second coating 21 are deposited at least partially by means of a PVD-process and/or a PACVD-process (PVD: Physical Vapor Deposition; PACVD: Plasma assisted chemical vapor deposition).

According to another preferred embodiment of the present invention the first coating 31 and/or the second coating 21 comprises aluminum and/or titanium.

Also preferred the first coating 31 and/or the second coating 21 comprises nitrogen and/or oxygen.

The inventors have also found, that coatings comprising titanium aluminum nitride or aluminum titanium nitride or are of titanium aluminum nitride or aluminum titanium nitride, are very suitable as first coating 31 and/or second coating 21 in the context of the present invention.

Also coatings comprising aluminum oxide or consisting of aluminum oxide are well suited as first coating 31 and/or second coating 21 in the context of the present invention.

The present invention also discloses a coating system with a vacuum chamber according to the invention as coating chamber, as described above.

According to a preferred embodiment of a coating system according to the invention, the coating chamber is established as a PVD-coating chamber.

A shielding wall (30) is preferably provided for reducing or avoiding coating of the inner chamber wall side during performing a PVD-process inside the PVD-coating chamber.

Both top surfaces and bottom surfaces of the PVD-coating chamber are preferably thermally insulated, to realize a more homogeneous distribution of temperature over the coating height (respectively over the entire height of the treatment area).

The chamber wall 20 or the chamber walls 20, respectively, are preferably not provided with functional elements such as coating elements, plasma treating elements or heating elements.

As required, all chamber walls 20, at which preferably no such functional elements are arranged, can be provided with a second coating 21 in the inner chamber wall side and provided with a shielding wall 30 with a first coating 31 according to the present invention.

It can also be advantageous, that all these chamber walls 20 are provided with integrated cooling systems 15 for realizing an even higher heat removal.

As already mentioned above, FIG. 2 shows the comparison of the course of the substrate temperature in the same vacuum chamber, whereby once for the embodiment according to the invention, shielding walls 30 and chamber walls 20, as described above, are provided with corresponding first coatings 31 and second coatings 21 according to the invention (solid line), and another time for the example to the state of the art the same vacuum chamber arrangement was used, but without coatings 31 and 21 (broken line). Both examples were performed with equal heat supply into the coating chamber.

For the above mentioned embodiment according to the invention, a PVD deposited titanium aluminum nitride coating with an emission coefficient ε from about 0.9 was used as first coating 31 as well as second coating 21.

According to a preferred embodiment of the present invention the inner side of all shielded chamber walls can be coated at least largely with a corresponding second coating 21 and the side of all shielding walls opposite to the chamber walls at least largely with a corresponding first coating 31.

According to the present invention both the coating 21 and the coating 31 should be made of materials, which are vacuum suitable.

It is also important, that these materials are not magnetic, to avoid malfunctions during coating.

The coatings 21 and/or 31 preferably have at least one of the following characteristics:
a coating thickness not larger than 50 μm,
a dense coating structure, so that there is possibly no outgassing by the coating,
a good adhesion to the carrier material for ensuring a good heat transfer,
a high temperature stability, which allows performing coating processes at increased temperatures, preferred up to at least 600° C.,
good abrasion resistance, so that these coatings are not rapidly worn off in a “harsh production environment”.

The coatings 21 and/or 31 are preferably deposited by means of PVD techniques, so that they can be applied, for example, on the corresponding chamber wall sides and shielding walls sides in the same coating chamber. In this case, for example, the inner chamber walls can first be coated with the coating 21 without shielding walls in a coating process. Afterwards, however, the shielding walls can be placed in the opposite direction in the coating chamber, so that the desired shielding wall side, which will be later opposite the inner chamber wall side, can be coated with the coating 31. A single application of the coatings 21 and 31 is sufficient, in order to operate the coating system several times with a coating chamber provided according to the invention.

For performing a PVD coating process for coating substrates in a coating chamber according to the invention, the shielding walls are arranged in the coating system such, that the inner chamber walls or the inner side of the chamber walls, respectively are protected in order to minimize or to avoid an undesired coating of these walls. In this way, basically only the shielding wall side without a coating 31 is also coated during the coating of substrates. Therefore both the applied coating 31 and the applied coating 21 remain intact after each coating process.

1. Vacuum chamber for the treatment of substances, comprising at least the following elements:
heat supply elements for the heat supply into a treatment area of the vacuum chamber, in which at least one substrate (10) can be treated,
a chamber wall (20), through which heat can be removed from the treatment area, comprising an inner and an outer chamber wall side, and
a shielding wall (30), which is arranged between the chamber wall (20) and the treatment area, such that an averted shielding wall side with respect to the treatment area is placed opposite the inner chamber wall side,
and characterized in, that
the shielding wall side placed opposite the inner chamber wall side is at least partially, preferred largely applied with a first coating (31), having an emission coefficient ε≧0.65.

2. Vacuum chamber according to claim 1, characterized in, that the inner chamber wall side is at least partially, preferred at least largely applied with a second coating (21), having an emission coefficient ε≧0.65.

3. Vacuum chamber according to claim 1, characterized in, that the chamber wall (20) comprises an integrated cooling system (15).

4. Vacuum chamber according to claim 1, characterized in, that the emission coefficient of the first coating (31) is higher than or equal to 0.80, preferably higher than or equal to 0.90.

5. Vacuum chamber according to claim 1, characterized in, that the emission coefficient of the first coating (21) is higher than or equal to 0.80, preferably higher than or equal to 0.90.

6. Vacuum chamber according to claim 1, characterized in, that the first coating (31) and/or the second coating (21) were deposited at least partially by means of a PVD-process and/or a PA-CVD-process.

7. Vacuum chamber according to claim 1, characterized in, that the first coating (31) and/or the second coating (21) comprises aluminum and/or titanium.

8. Vacuum chamber according to claim 1, characterized in, that the first coating (31) and/or the second coating (21) comprises nitrogen and/or oxygen.

9. Vacuum chamber according to claim 7, characterized in, that the first coating (31) and/or the second coating (21) comprises titanium aluminum nitride or aluminum titanium nitride.

10. Vacuum chamber according to claim 8, characterized in, that the first coating (31) and/or the second coating (21) comprises aluminum oxide.

11. Coating system with a vacuum chamber as coating chamber according to claim 1.

12. Coating system according to claim 11, characterized in, that the coating chamber is established as a PVD-coating chamber.

13. Coating system according to claim 12, characterized in, that the shielding wall (30) is provided for reducing or avoiding coating of the inner chamber wall side during performing a PVD process inside the PVD coating chamber.

14. Coating system according to claim 12, characterized in, that top surfaces and bottom surfaces of the PVD coating chamber are thermally insulated.
